(19) United States
(12) Patent Application Publication
(10) Pub. No.: US 2024/0341159 A1
(43) Pub. Date: Oct. 10, 2024

(54) DISPLAY PANEL, METHOD FOR PREPARING A DISPLAY PANEL, AND DISPLAY DEVICE

(71) Applicant: Xiamen Tianma Display Technology Co., Ltd., Xiamen (CN)

(72) Inventors: Jiansheng ZHONG, Xiamen (CN); Jinjin YANG, Xiamen (CN); Shui HE, Xiamen (CN)

(73) Assignee: Xiamen Tianma Display Technology Co., Ltd., Xiamen (CN)

(21) Appl. No.: 18/749,229

(22) Filed: Jun. 20, 2024

(30) Foreign Application Priority Data
Oct. 25, 2023 (CN) 202311394525.3

(51) Int. Cl. H10K 59/80; H10K 59/12

(52) U.S. Cl. CPC H10K 59/879; H10K 59/1201; H10K 59/873

(57) ABSTRACT

A display panel includes a substrate, multiple light-emitting units, multiple microlens portions, and a refractive layer. Each microlens portion is disposed on a side of each light-emitting unit facing away from the substrate. The microlens portion includes an etch-resistant material. The refractive layer is disposed at least on a side of the microlens portion facing away from the substrate. The refractive index of the refractive layer is greater than the refractive index of the microlens portion.

### CROSS-REFERENCE TO RELATED APPLICATION

This application claims priority to Chinese Patent Application No. 202311394525.3 filed Oct. 25, 2023, the disclosure of which is incorporated herein by reference in its entirety.

### TECHNICAL FIELD

The present application belongs to the technical field of electronic products, for example, a display panel, a method for preparing a display panel, and a display device.

### BACKGROUND

As technology advances, digital display devices such as smart phones and tablet computers are widely used. Display panels are an indispensable interpersonal communication interface in these display devices. For example, an OLED (organic light-emitting diode) display panel has advantages such as self-luminescence, energy saving and consumption reduction, bendability, and good flexibility. Moreover, this display device for achieving display does not require a backlight and has the characteristics of fast response speed and good display effect. Thus, this display panel has attracted the attention of users and is widely used in terminal products such as smart phones and tablet computers.

However, due to the structural limitations of the existing display panels, the reliability of display panels cannot meet requirements.

Therefore, a new display panel, a method for preparing a display panel, and a display device are in urgent need.

### SUMMARY

Embodiments of the present application provide a display panel, a method for preparing a display panel, and a display device. After a microlens portion in the embodiments of the present application completes the blocking effect for a light-emitting unit during the preparation, the microlens portion does not need to be removed. Rather, the microlens portion may cooperate with a refractive layer to achieve a light-gathering effect, improve the light emission efficiency, and reduce power consumption. In this manner, the influence of a water washing process on the performance of the light-emitting unit can be avoided, and the reliability of the display panel can be improved.

In a first aspect, an embodiment of the present application provides a display panel. The display panel includes a substrate, multiple light-emitting units, multiple microlens portions, and a refractive layer. Multiple light-emitting units are disposed on one side of the substrate. Each microlens portion is disposed on a side of a respective one light-emitting unit facing away from the substrate. Each microlens portion includes an etch-resistant material. A refractive layer is disposed at least on a side of the multiple microlens portions facing away from the substrate. A refractive index of the refractive layer is greater than a refractive index of a microlens portion of the multiple microlens portions.

In a second aspect, an embodiment of the present application provides a display device. The display device includes the display panel in the preceding embodiment.

In a third aspect, an embodiment of the present application provides a method for preparing a display panel. The method includes following steps: providing a substrate; forming a light-emitting unit material layer on one side of the substrate; forming a plurality of microlens portions on a side of the light-emitting unit material layer facing away from the substrate, where the plurality of microlens portions include an etch-resistant material; etching the light-emitting unit material layer with the plurality of microlens portions as shields to form a plurality of light-emitting units; and forming a refractive layer at least on a side of the plurality of microlens portions facing away from the substrate, where a refractive index of the refractive layer is greater than a refractive index of a microlens portion of the plurality of microlens portions.

### BRIEF DESCRIPTION OF DRAWINGS

To illustrate technical solutions in embodiments of the present application more clearly, accompanying drawings used in the description of the embodiments are briefly described below. Apparently, the accompanying drawings described below illustrate part of embodiments of the present application, and those of ordinary skill in the art may acquire other accompanying drawings based on the accompanying drawings described below on the premise that no creative work is done.

FIG. 1 is a diagram illustrating the structure of a display panel according to an embodiment of the present application.

FIG. 2 is a sectional view of A-A in FIG. 1 according to an embodiment of the present application.

FIG. 3 is a sectional view of B-B in FIG. 1 according to an embodiment of the present application.

FIG. 4 is a sectional view of A-A in FIG. 1 according to another embodiment of the present application.

FIG. 5 is a diagram illustrating the optical path according to an embodiment of the present application.

FIG. 6 is a sectional view of a first light-emitting unit and a second light-emitting unit according to an embodiment of the present application.

FIG. 7 is a flowchart of a method for preparing a display panel according to an embodiment of the present application.

FIG. 8 is a sectional view of a structure obtained by S110 in the method for preparing a display panel according to an embodiment of the present application.

FIG. 9 is a sectional view of a structure obtained by S120 in the method for preparing a display panel according to an embodiment of the present application.

FIG. 10 is a sectional view of a structure obtained by S130 in the method for preparing a display panel according to an embodiment of the present application.

FIG. 11 is a sectional view of a structure obtained by S140 in the method for preparing a display panel according to an embodiment of the present application.

FIG. 12 is a sectional view of a structure obtained by S150 in the method for preparing a display panel according to an embodiment of the present application.

FIG. 13 is a sectional view of a structure of a display panel obtained during the preparation process according to an embodiment of the present application.

### DETAILED DESCRIPTION

Features of various aspects and exemplary embodiments of the present application are described in detail below. In the following detailed description, numerous specific details are set forth to provide a thorough understanding of the present application. However, it is apparent to those skilled in the art that the present application may be implemented without some of these specific details. The description of the embodiments below is only to provide a better understanding of the present application by illustration of examples of the present application.

It is to be noted that in the present application, relationship terms such as first and second are used merely to distinguish one entity or operation from another entity or operation and do not necessarily require or imply any such actual relationship or order between these entities or operations. Additionally, the term “comprising”, “including”, or any other variant thereof is intended to encompass a non-exclusive inclusion so that a process, method, article, or device that includes a series of elements not only includes the expressly listed elements but also includes other elements that are not expressly listed or elements inherent to such a process, method, article, or device. In the absence of more restrictions, the elements defined by the statement “including a . . . ” do not exclude the presence of additional identical elements in the process, method, article, or device that includes the elements.

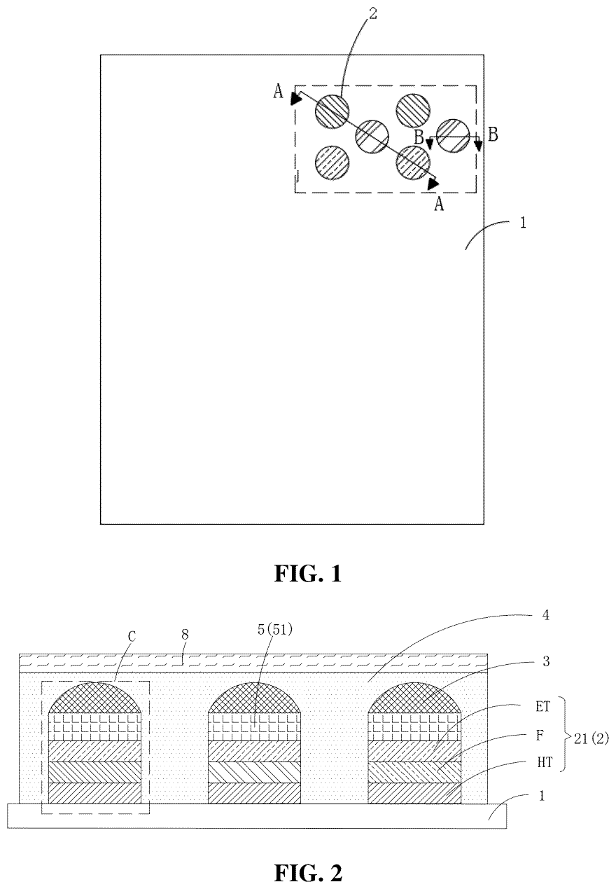

To better understand the present application, the display panel, the method for preparing a display panel, and a display device according to embodiments of the present application are described in detail below with reference to FIGS. 1 to 13.

With reference to FIGS. 1 and 2, FIG. 1 is a diagram illustrating the structure of a display panel according to an embodiment of the present application; FIG. 2 is a sectional view of A-A in FIG. 1 according to an embodiment of the present application.

An embodiment of the present application provides a display panel. The display panel includes a substrate 1, multiple light-emitting units 2, multiple microlens portions 3, and a refractive layer 4. Multiple light-emitting units 2 are disposed on one side of the substrate 1. Each microlens portion 3 is disposed on a side of a respective one light-emitting unit 2 of the multiple light-emitting units 2 facing away from the substrate 1. The microlens portions 3 include an etch-resistant material. A refractive layer 4 is disposed at least on a side of the microlens portion 3 facing away from the substrate 1. The refractive index of the refractive layer 4 is greater than the refractive index of the microlens portion 3.

The display panel provided by embodiments of the present application includes a substrate 1, light-emitting units 2, microlens portions 3, and a refractive layer 4. In this embodiment, since the microlens portions 3 include an etch-resistant material, the microlens portions 3 can play a blocking role when a light-emitting unit 2 is formed, that is, multiple independent light-emitting units 2 may be formed by using multiple patterned microlens portions 3. In the related art, the photoresist is used for achieving a blocking effect during the preparation of the light-emitting unit 2, and then the photoresist needs to be removed and washed through the de-bonding and water washing manufacturing process. Compared with the photoresist, the microlens portion 3 in this embodiment of the present application does not need to be removed after completing the blocking effect on the light-emitting unit 2 during preparation. Rather, the microlens portion 3 may cooperate with the refractive layer 4 to achieve a light-gathering effect, improve the light emission efficiency, and reduce power consumption. In this manner, the influence of a water washing process on the performance of the light-emitting unit 2 can be avoided, and the reliability of the display panel can be improved.

In this embodiment, the microlens portion 3 includes an etch-resistant material, and when the material of a light-emitting unit 2 is etched, the material of a portion of the light-emitting unit 2 shielded by the microlens portion 3 is not etched, so as to correspondingly form the light-emitting unit 2.

It can be understood that the refractive layer 4 is disposed on a side of the microlens portion 3 facing away from the substrate 1, and the refractive index of the refractive layer 4 is greater than the refractive index of the microlens portion 3, that is, the light emitted from the light-emitting unit 2 is incident from the microlens portion 3 into the refractive layer 4. In other words, the light emitted from the light-emitting unit 2 enters an optically dense medium from an optically thin medium, and light from all directions can be converged into the light emitted from a positive viewing angle. The positive viewing angle may be understood as a viewing angle in a direction from the substrate 1 to the light-emitting unit 2, so as to improve the light emission efficiency and reduce power consumption.

The substrate 1 may be a hard substrate such as a glass substrate and may also be a flexible substrate. The material of the flexible substrate may be polyimide, polystyrene, polyethylene terephthalate, polyparaxylene, polyethersulfone, or polyethylene naphthalate. The substrate 1 is primarily used for supporting devices arranged on the substrate 1.

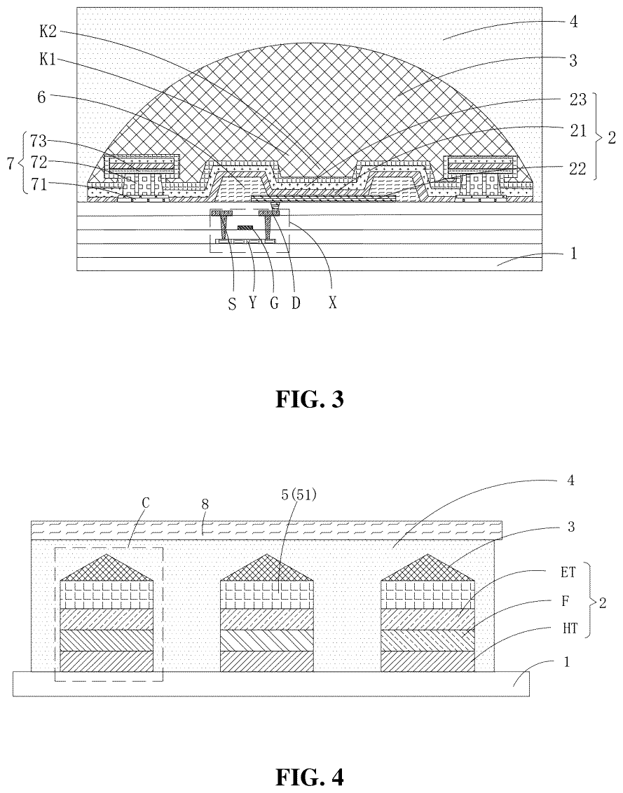

With reference to FIG. 3, FIG. 3 is a sectional view of B-B in FIG. 1 according to an embodiment of the present application; the light-emitting unit 2 includes a first electrode layer 22, a light-emitting layer 21, and a second electrode layer 23 that are stacked in a direction away from the substrate 1. One of the first electrode layer 22 and the second electrode layer 23 is an anode, and the other is a cathode. In this embodiment of the present application, an example is used for illustration where the second electrode layer 23 is the cathode, and the first electrode layer 22 is the anode.

In some embodiments, the light-emitting layer 21 includes one or more of an electron injection layer (not shown), an electron transport layer ET, a light-emitting material layer F, a hole blocking layer (not shown), an electron blocking layer (not shown), a hole transport layer HT, and a hole injection layer. The specific selection may be made according to the specific type of the light-emitting layer 21 and is not particularly limited. The electron injection layer, the electron transport layer ET, and the hole blocking layer may be disposed between the second electrode layer 23 and the light-emitting material layer F. The electron blocking layer, the hole transport layer HT, and the hole injection layer may be disposed between the first electrode layer 22 and the light-emitting material layer F.

The material of the first electrode layer 22 is generally a material having a high work function to improve the hole injection efficiency. The material may be gold (Au), platinum (Pt), titanium (Ti), silver (Ag), indium tin oxide (ITO), zinc tin oxide (IZO), or a transparent conductive polymer (such as polyaniline). For example, the first electrode layer 22 may be made of an ITO-Ag-ITO composite material, and the material is not particularly limited.

The material of the second electrode layer 23 may be one of metallic materials such as silver (Ag), aluminum (Al), lithium (Li), magnesium (Mg), ytterbium (Yb), calcium (Ca), or indium (In) or may be an alloy of the preceding metallic materials, such as a magnesium-silver alloy (Mg/Ag) or a lithium-aluminum alloy (Li/Al), which is not limited in this embodiment.

With reference to FIG. 3, in some embodiments, the display panel also includes a pixel circuit layer X disposed between the substrate 1 and the light-emitting unit 2. The pixel circuit layer X may include a first conductive layer, a second conductive layer, and a third conductive layer that are stacked on one side of the substrate. An insulating layer is disposed between adjacent conductive layers. Illustratively, the pixel circuit layer X includes a transistor and a storage capacitor (not shown). The transistor includes an active layer Y, a gate G, a source S, and a drain D. The storage capacitor includes a first plate and a second plate. As an example, the gate G and the first plate may be disposed in the first conductive layer, the second plate may be disposed in the second conductive layer, and the source S and the drain D may be disposed in the third conductive layer.

In some embodiments, the display panel also includes a pixel defining layer 6 disposed on one side of the substrate 1, and the pixel defining layer 6 has a pixels opening K2; the light-emitting unit 2 is at least partially disposed in the pixel opening K2.

In some embodiments, a planarization layer (not shown) may be disposed between the substrate 1 and the pixel defining layer 6, and the material of the planarization layer may be hexamethyldisiloxane, epoxy resin, or polyimide as well as other materials, which is not limited in this embodiment.

With reference to FIG. 3, in some optional embodiments, the display panel also includes an isolation structure 7 disposed on one side of the substrate 1; the isolation structure 7 includes an isolation opening K1, the light-emitting unit 2 is at least partially located within the isolation opening K1, and the orthographic projection of the microlens portion 3 on the substrate 1 covers the orthographic projection of the isolation structure 7 on the substrate 1.

In this embodiment, the light-emitting layer 21 can be isolated by the configuration of the isolation structure 7 to avoid problems such as crosstalk between light-emitting units 2; the second electrode layer 23 may overlap the isolation structure 7, that is, the isolation structure 7 is made of a conductive material. In this manner, the electrical connection between the second electrode layers 23 in adjacent isolation openings K1 is achieved through the isolation structure 7 to facilitate the unified transmission of electrical signals to the second electrode layer 23.

In some embodiments, in any of the preceding embodiments, the isolation structure 7 is integrally provided; alternatively, the isolation structure 7 includes multiple sub-layers stacked in the direction of the thickness of the display panel. The isolation structure 7 is configured to include multiple sub-layers. By the selection of materials of different sub-layers, it is convenient to prepare the isolation structure 7 into a target pattern and to improve the structure of the isolation structure 7.

To connect the second electrode layers 23 in adjacent isolation openings K1, the material of the isolation structure 7 may be a conductive metal material. The isolation structure 7 may specifically be a single-layer metal, for example, silver (Ag), aluminum (Al), lithium (Li), titanium (Ti), and molybdenum (Mu). Alternatively, the isolation structure 7 may adopt a laminated metal structure, for example, a titanium-aluminum-titanium laminated metal structure or a titanium-aluminum-molybdenum laminated metal structure. Of course, the material of the isolation structure 7 may be another conductive material without special limitations.

In some embodiments, in the direction away from the substrate 1, the isolation structure 7 includes a first sub-layer 71, a second sub-layer 72, and a third sub-layer 73 arranged in a stack; the first sub-layer 71 may adopt a titanium metal layer, the second sub-layer 72 may adopt an aluminum metal layer, and the third sub-layer 73 may adopt a titanium metal layer.

In some embodiments, the orthographic projection of the second sub-layer 72 on the substrate 1 is located within each of the orthographic projections of the first sub-layer 71 and the third sub-layer 73 on the substrate 1. Therefore, the size of the second sub-layer 72 is smaller than or equal to each of the size of the first sublayer 71 and the size of the third sublayer 73 so that the second electrode layer 23 can overlap the second sub-layer 72.

With reference to FIG. 2 or FIG. 4, FIG. 4 is a sectional view of A-A in FIG. 1 according to another embodiment of the present application; in some optional embodiments, the microlens portion 3 has a tapered structure in the direction from the substrate 1 to the light-emitting unit 2.

The microlens portion 3 having a tapered structure may indicate that the cross-sectional width of the microlens portion 3 gradually decreases in the direction from the substrate 1 to the light-emitting unit 2. In this manner, the light emitted from the light-emitting unit 2 can be concentrated toward the middle of the microlens portion 3, and the microlens portion 3 and the refractive layer 4 cooperate to achieve a light-gathering effect, improve the light emission efficiency, and reduce power consumption. Thus, the influence of a water washing process on the performance of the light-emitting unit 2 is avoided, and the reliability of the display panel is improved.

In some embodiments, the cross section of the microlens portion 3 is at least one of a semicircle (as shown in FIG. 1), a triangle (as shown in FIG. 4), or a trapezoid in a direction perpendicular to a plane in which the substrate is located.

In this embodiment, the microlens portion 3 may have a structure similar to a convex lens. The convex lens is thicker in the center and thinner at the edges. The convex lens, having a light-converging function, is also called a converging lens. A thicker convex lens has the function of converging light. For example, the cross section of the microlens portion 3 in this embodiment may be semicircular, and the microlens portion 3 protrudes in a direction away from the substrate 1, that is, the microlens portion 3 is generally hemispherical; alternatively, the cross section of the microlens portion 3 may be an isosceles triangle, and the microlens portion 3 protrudes in a direction away from the substrate 1. Of course, as required, the microlens portion 3 may also adopt other structural forms without special limitations.

With reference to FIG. 2 or FIG. 4, in some optional embodiments, the display panel also includes a first inorganic layer 5 and a second inorganic layer 8; the first inorganic layer 5 includes multiple first inorganic portions 51, each first inorganic portion 51 is disposed between the light-emitting unit 2 and the microlens portion 3, and the second inorganic layer 8 is disposed on a side of the reflective layer 4 facing away from the substrate 1.

It should be noted that in this embodiment, the first inorganic layer 5 includes multiple first inorganic portions 51, the first inorganic portions 51 are arranged with spacings, and each first inorganic portion 51 corresponds to a different light-emitting unit 2 and a different microlens portion 3, that is, the light-emitting unit 2 and the microlens portion 3 are separately encapsulated by each first inorganic portion 51. Thus, individual encapsulation is achieved, and the reliability of the display panel encapsulation is enhanced.

In some embodiments, the first inorganic layer 5 may cover the isolation structure 7 and enclose the entire isolation structure 7 to result in a single-pixel encapsulation effect to prevent water vapor from damaging the light-emitting unit 2 after the light-emitting layer 21 is etched.

In some embodiments, in this embodiment, the refractive layer 4 may extend between adjacent microlens portions 3 and between adjacent light-emitting units 2 so that adjacent first inorganic portions 51 are separated by the refractive layer 4.

By the configuration of the second inorganic layer 8 on the side of the refractive layer 4 facing away from the substrate 1, external water and oxygen are prevented from corroding the refractive layer 4 or the microlens portion 3, and the light-gathering effect of the refractive layer 4 and the microlens portion 3 is ensured.

In some embodiments, the first inorganic layer 5 and the second inorganic layer 8 may be prepared using one of silicon nitride, silicon oxide, or silicon oxynitride.

With reference to FIG. 2 or FIG. 4, in some optional embodiments, the light-emitting unit 2, the first inorganic portion 51, and the microlens portion 3, which are stacked, constitute each stacked unit C of stacked units C; in a direction parallel to the plane in which substrate is located, the stacked units C are arranged with spacings, and part of a refractive layer 4 extends into the space between two of the stacked units C.

It should be noted that each stacked unit C includes a light-emitting unit 2, a first inorganic portion 51, and a microlens portion 3, which are stacked in a direction away from the plane in which the substrate 1 is located; the stacked units C are spaced apart from each other, and part of the refractive layer 4 extends into the space between the stacked units C. Thus, each stacked unit C is spaced apart from other stacked units C and independently arranged to avoid mutual interference between the light emitted from the stacked units C.

In some optional embodiments, the microlens portion 3 has the refractive index ranging from 1.4 to 1.6; and/or, the refractive layer 4 has the refractive index ranging from 1.6 to 1.8.

With reference to FIG. 5, FIG. 5 is a diagram illustrating the optical path according to an embodiment of the present application; sinθ1/sinθ2=n2/n1, n1 is the refractive index of the refractive layer 4, and n2 is the refractive index of the microlens portion 3.

It is necessary to ensure that the refractive index of the microlens portion 3 is smaller than the refractive index of the refractive layer 4 so that the light emitted from the interface between the microlens portion 3 and the refractive layer 4 is deflected toward the center line of the microlens portion 3 to achieve a light-gathering effect. For example, when the refractive index of the microlens portion 3 is equal to 1.4, the refractive index of the refractive layer 4 may be 1.6, 1.7, or 1.8; alternatively, when the refractive index of the microlens portion 3 is equal to 1.6, the refractive index of the refractive layer 4 may be 1.7, or 1.8. No special limit is imposed.

In some optional embodiments, the light-emitting unit 2 includes a first light-emitting unit P1 and a second light-emitting unit P2, and the wavelength of light emitted by the first light-emitting unit P1 is greater than the wavelength of light emitted by the second light-emitting unit P2; the refractive index of the microlens portion 3 disposed on a side of the first light-emitting unit P1 facing away from the substrate 1 is greater than the refractive index of the microlens portion 3 disposed on a side of the second light-emitting unit P2 facing away from the substrate 1.

In this embodiment, the light-emitting unit 2 generally employs three light-emitting colors of red, blue, and green, the wavelength of red light is greater than the wavelength of green light, and the wavelength of green light is greater than the wavelength of blue light. Therefore, the first light-emitting unit P1 and the second light-emitting unit P2 in this embodiment may be a red light-emitting unit 2 and a green light-emitting unit 2, respectively, may be a red light-emitting unit 2 and a blue light-emitting unit 2, respectively, or may be a green light-emitting unit 2 and a blue light-emitting unit 2, respectively.

It can be understood that the larger the wavelength is, the smaller the refractive index is. The wavelength of the light emitted by the first light-emitting unit P1 is greater than the wavelength of the light emitted by the second light-emitting unit P2. That is, in the same medium, the refractive index corresponding to the light emitted by the first light-emitting unit P1 is smaller than the refractive index corresponding to the light emitted by the second light-emitting unit P2, and the wavelength is smaller. Therefore, in this embodiment, the refractive index of the microlens portion 3 disposed on a side of the first light-emitting unit P1 facing away from the substrate 1 may be configured to be greater than the refractive index of the microlens portion 3 disposed on a side of the second light-emitting unit P2 facing away from the substrate 1 so that the uniformity of the refraction effect is improved when the light of different colors of the first light-emitting unit P1 and the second light-emitting unit P2 is emitted from the microlens portion 3. That is, by the adjustment of the refractive index of the microlens portion 3 disposed on a side of the first light-emitting unit P1 facing away from the substrate 1 and the refractive index of the microlens portion 3 disposed on a side of the second light-emitting unit P2 facing away from the substrate 1, the difference in refraction effects caused by the different wavelengths of light emitted by the first light-emitting unit P1 and the second light-emitting unit P2 is reduced.

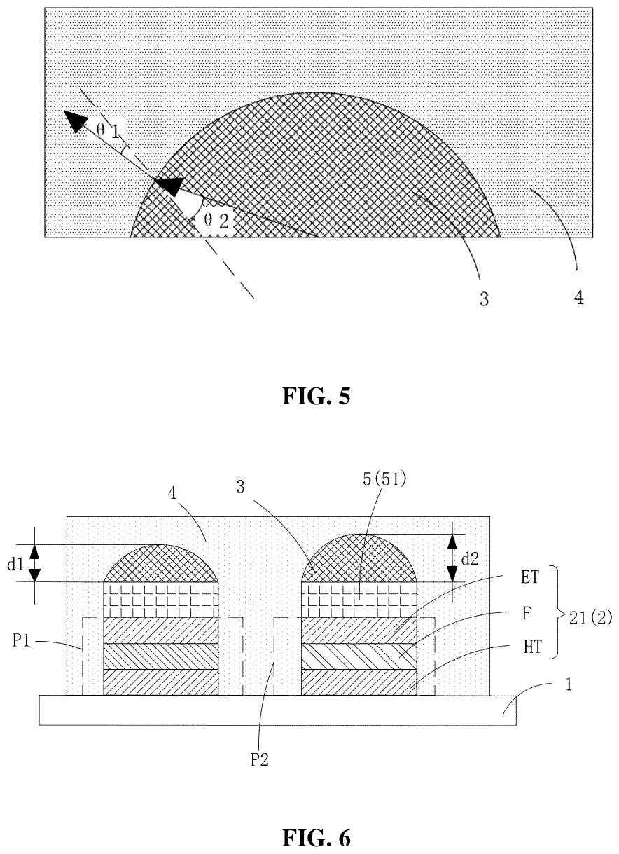

With reference to FIG. 6, FIG. 6 is a sectional view of a first light-emitting unit P1 and a second light-emitting unit P2 according to an embodiment of the present application; in some optional embodiments, the light-emitting unit 2 includes a first light-emitting unit P1 and a second light-emitting unit P2, and the wavelength of light emitted by the first light-emitting unit P1 is greater than the wavelength of light emitted by the second light-emitting unit P2; in a direction perpendicular to the plane in which the substrate is located, the thickness d1 of the microlens portion 3 disposed on a side of the first light-emitting unit P1 facing away from the substrate 1 is smaller than the thickness d2 of the microlens portion 3 disposed on a side of the second light-emitting unit P2 facing away from the substrate 1.

The inventor finds via research that the thinner the thickness of the microlens portion 3 is, the higher the refractive index is. That is, the thickness of the microlens portion 3 affects the refraction effect of the light emitted by the light-emitting unit 2 at the microlens portion 3. The thickness d1 of the microlens portion 3 disposed on a side of the first light-emitting unit P1 facing away from the substrate 1 is configured to be smaller than the thickness d2 of the microlens portion 3 disposed on a side of the second light-emitting unit P2 facing away from the substrate 1 so that the refractive index of the microlens portion 3 disposed on a side of the first light-emitting unit P1 facing away from the substrate 1 is greater than the refractive index of the microlens portion 3 disposed on a side of the second light-emitting unit P2 facing away from the substrate 1. Moreover, the difference in refraction effects caused by the different wavelengths of light emitted by the first light-emitting unit P1 and the second light-emitting unit P2 is reduced, and the uniformity of light emission effects of the first light-emitting unit P1 and the second light-emitting unit P2 is improved.

In some optional embodiments, the microlens portion 3 and the refractive layer 4 each include an acrylic material. It should be noted that the acrylic material is also called PMMA (Polymeric Methyl Methacrylate) or organic glass. The microlens portion 3 and the refractive layer 4 each include an acrylic material, but the specific components of the acrylic material and the production process may be adjusted to make the refractive index of the microlens portion 3 and the refractive layer 4 different to satisfy the refractive index requirements for the microlens portion 3 and the refractive layer 4 in this embodiment.

In some embodiments, the refractive layer 4 includes a zirconium oxide material. Specifically, the acrylic material of the refractive layer 4 may be doped with a zirconium oxide material. By the doping of the zirconium oxide material, the refractive index of the refractive layer 4 can be increased, and the hardness, wear resistance, high temperature resistance, chemical stability, and other properties of the refractive layer 4 can also be improved.

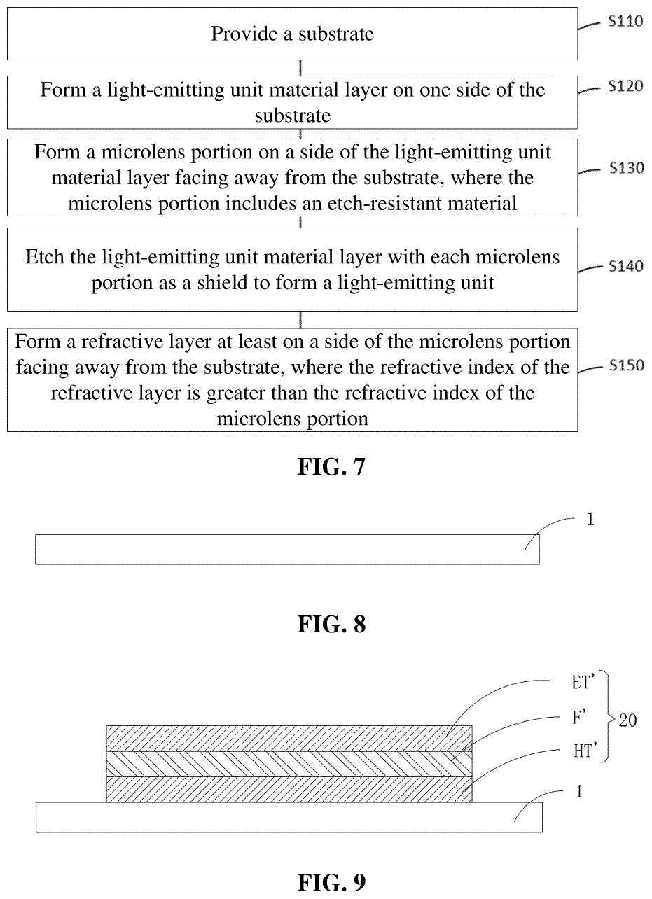

With reference to FIG. 7, an embodiment of the present application also provides a method for preparing a display panel. The method includes the steps described blew.

In S110, a substrate 1 is provided, as shown in FIG. 8.

In S120, a light-emitting unit material layer 20 is formed on one side of the substrate 1, as shown in FIG. 9.

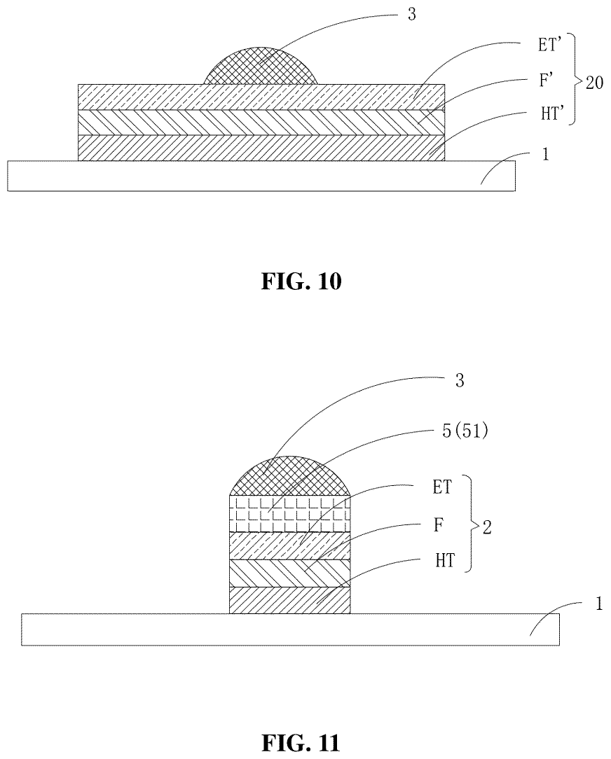

In S130, a microlens portion 3 is formed on a side of the light-emitting unit material layer 20 facing away from the substrate 1, and the microlens portion 3 includes an etch-resistant material, as shown in FIG. 10.

In S140, the light-emitting unit material layer 20 is etched with each microlens portion 30 as a shield to form a light-emitting unit 2, as shown in FIG. 11.

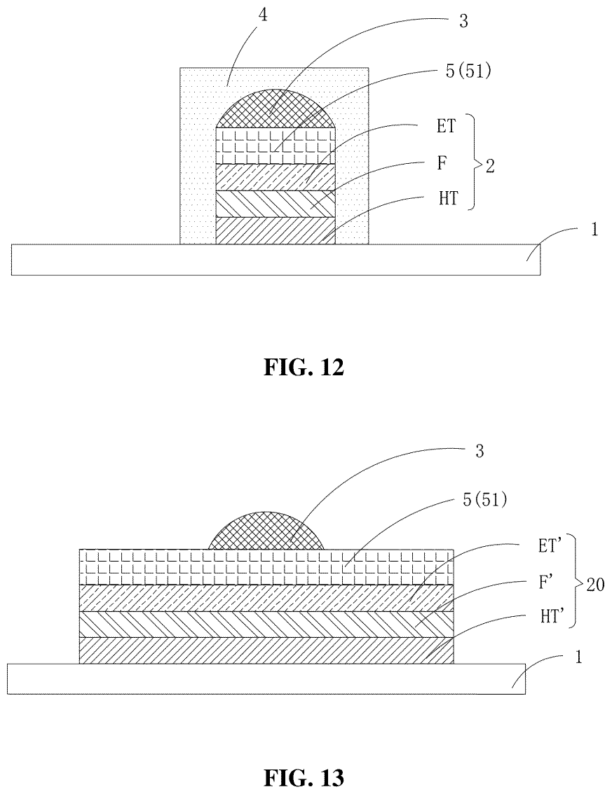

In S150, a refractive layer 4 is formed at least on a side of the microlens portion 3 facing away from the substrate 1, and the refractive index of the refractive layer 4 is greater than the refractive index of the microlens portion 3, as shown in FIG. 12.

In the method for preparing a display panel according to this embodiment of the present application, the microlens portion 3 includes an etch-resistant material, and when the material of the light-emitting unit 2 is etched, the material of a portion of the light-emitting unit 2 shielded by the microlens portion 3 is not etched, so as to correspondingly form the light-emitting unit 2. In the related art, the photoresist is used for achieving a blocking effect during the preparation of the light-emitting unit 2, and the photoresist needs to be peeled off and washed. Compared with the photoresist, the microlens portion 3 in this embodiment of the present application does not need to be removed after completing the blocking effect on the light-emitting unit 2 during preparation.

Rather, the microlens portion 3 may cooperate with the refractive layer 4 to achieve a light-gathering effect, improve the light emission efficiency, and reduce power consumption. In this manner, the influence of a water washing process on the performance of the light-emitting unit 2 is avoided, and the reliability of the display panel is improved.

In S110, the substrate 1 may be formed through processes such as coating, curing, and film formation. The substrate 1 may be a hard substrate such as a glass substrate and may also be a flexible substrate. The material of the flexible substrate may be polyimide, polystyrene, polyethylene terephthalate, polyparaxylene, polyethersulfone, or polyethylene naphthalate. The substrate 1 is primarily used for supporting devices arranged on the substrate 1.

In S120, when the light-emitting unit material layer 20 is formed, the materials of multiple layers of the light-emitting unit material layer 20 may be formed by evaporation or other processes, such as a light-emitting material F′, an electron transport material layer ET′, and a hole transport material layer HT′.

In S130, the microlens portion 3 may be made of an acrylic material. The acrylic material is not affected by the etching solution, that is, the microlens portion 3 is not etched by the etching solution used for etching the light-emitting unit material layer 20 and does not need to be peeled off and washed; the microlens portion 3 may be retained to improve the light emission efficiency.

In S140, the light-emitting unit material layer 20 is etched with each microlens portion 3 as a shield, that is, the microlens portion 3 serves as a shield of the photoresist, and compared to the photoresist, the microlens portion 3 may be retained in the display panel does not need to be removed.

In S150, the refractive layer 4 may also be made of an acrylic material, and the specific components of the acrylic material and the production process may be adjusted to make the refractive index of the microlens portion 3 and the refractive layer 4 different to satisfy the refractive index requirements for the microlens portion 3 and the refractive layer 4 in this embodiment.

With reference to FIG. 13, FIG. 13 is a sectional view of a structure of a display panel obtained during the preparation process according to an embodiment of the present application. In some optional embodiments, between forming the light-emitting unit material layer 20 on the one side of the substrate 1 and forming the microlens portion 3 on the side of the light-emitting unit material layer 20 facing away from the substrate 1, where the microlens portion 3 includes the etch-resistant material, the method also includes forming a first inorganic layer 5 on the side of the light-emitting unit material layer 20 facing away from the substrate 1; etching the light-emitting unit material layer 20 with each microlens portion 3 as the shield to form the light-emitting unit 2 includes etching the first inorganic layer 5 and the light-emitting unit material layer 20 with each microlens portion 3 as the shield to form a first inorganic portion 51 and the light-emitting unit 2.

It should be noted that the microlens portion 3 is used as a shield to etch the first inorganic layer 5 to form patterned first inorganic portions 51, each first inorganic portion 51 is arranged at intervals, and each first inorganic portion 51 corresponds to a different light-emitting unit 2 and a different microlens portion 3, that is, the light-emitting unit 2 and the microlens portion 3 are separately encapsulated by each first inorganic portion 51. Thus, individual encapsulation is achieved, and the reliability of the display panel encapsulation is enhanced.

In some embodiments, in this embodiment, the refractive layer 4 may extend between adjacent microlens portions 3 and between adjacent light-emitting units 2 so that adjacent first inorganic portions 51 are separated by the refractive layer 4.

Optionally, by the configuration of a second inorganic layer 8 on the side of the refractive layer 4 facing away from the substrate 1, external water and oxygen are prevented from corroding the refractive layer 4 or the microlens portion 3, and the light-gathering effect of the refractive layer 4 and the microlens portion 3 is ensured.

In some embodiments, the first inorganic layer 5 and the second inorganic layer 8 may be prepared using one of silicon nitride, silicon oxide, or silicon oxynitride. The first inorganic layer 5 and the second inorganic layer 8 may be prepared by chemical vapor deposition so that the density of the first inorganic layer 5 and the second inorganic layer 8 can be improved, and then the encapsulation effect can be enhanced.

In some optional embodiments, forming the microlens portion 3 on the side of the light-emitting unit material layer 20 facing away from the substrate 1 includes forming the microlens portion 3 on the side of the light-emitting unit material layer 20 facing away from the substrate 1 by inkjet printing.

The inkjet printing technique, that is, IJP technique, specifically includes the following: Via a computer, graphic information is converted into pulse electrical signals and transmitted to inkjet equipment. An inkjet control system calculates the amount of ink used in the corresponding channel and controls the ink to be ejected to a specific surface position of the substrate so that the surface of the substrate can reproduce the graphic information. In this embodiment, the material for preparing the microlens portion 3 is ejected to a side of the light-emitting unit material layer 20 facing away from the substrate 1 by the inkjet equipment, and the patterned microlens portion 3 is in no need to be formed by etching or other methods. The technique process is simple and convenient. Of course, the microlens portion 3 may be formed by another technique method, which is not particularly limited.

In some optional embodiments, forming the refractive layer 4 at least on the side of the microlens portion 3 facing away from the substrate 1 includes forming the refractive layer 4 at least on the side of the microlens portion 3 facing away from the substrate 1 by inkjet printing.

It can be understood that since both the refractive layer 4 and the microlens portion 3 may be made of an acrylic material, the refractive layer 4 and the microlens portion 3 may be prepared using the same preparation process, that is, both the refractive layer 4 and the microlens portion 3 may be prepared using an inkjet printing process to reduce the production cost and facilitate the preparation; according to the different requirements for the refractive index of the refractive layer 4 and the microlens portion 3, the specific components of the refractive layer 4 and the microlens portion 3 may be adjusted accordingly, and the refractive index can be adjusted by adding additional materials such as zirconium oxide.

An embodiment of the present application also provides a display device including the display panel in any of the preceding embodiments.

The display device provided by this embodiment of the present application has the technical effects of the technical solutions of the display panel in any one of the preceding embodiments, and the same or corresponding structure and the explanation of terms as those in the preceding embodiments are not repeated herein.

The display device provided by this embodiment of the present application may be an organic light-emitting diode (OLED for short) display device, quantum dot light-emitting diode (QLED for short) display device, or a Micro-OLED or Micro-LED display device.

The display device provided by the embodiments of the present application may be applied to mobile phones or any electronic product with a display function, including but not limited to the following categories: televisions, notebook computers, desktop monitors, tablet computers, digital cameras, smart bracelets, smart glasses, vehicle-mounted displays, medical equipment, industrial control equipment, and touch interactive terminals. Specific imitations are not imposed thereto by the embodiments of the present application.

The above are only specific implementations of the present application. It is apparent to those skilled in the art that to describe conveniently and briefly, for specific processes of operation of the systems, modules, and units, reference may be made to corresponding processes in the method embodiments, and repetition is not made herein. It should be understood that the above are not intended to limit the present application. It is easy for those skilled in the art to conceive equivalent modifications or substitutions within the technical scope of the present application. These modifications or substitutions are within the scope of the present application.

It should also be noted that the exemplary embodiments mentioned in the present application describe some methods or systems based on a series of steps or devices. However, the present application is not limited to the order of the preceding steps. That is to say, the steps may be performed in the order mentioned in the embodiments or in an order different from that in the embodiments, or several steps may be performed simultaneously.

What is claimed is:

1. A display panel, comprising:
a substrate;
a plurality of light-emitting units, disposed on one side of the substrate;
a plurality of microlens portions, wherein each microlens portion of the plurality of microlens portions is disposed on a side of a respective one light-emitting unit of the plurality of light-emitting units facing away from the substrate, and each microlens portion comprises an etch-resistant material; and
a refractive layer, disposed at least on a side of the plurality of microlens portions facing away from the substrate, wherein a refractive index of the refractive layer is greater than a refractive index of a microlens portion of the plurality of microlens portions.

2. The display panel of claim 1, wherein the microlens portion has a tapered structure in a direction from the substrate to a light-emitting unit of the plurality of light-emitting units.

3. The display panel of claim 2, wherein a cross section of the microlens portion is at least one of a semicircle, a triangle, or a trapezoid in a direction perpendicular to a plane in which the substrate is located.

4. The display panel of claim 1, further comprising a first inorganic layer and a second inorganic layer, wherein the first inorganic layer comprises a plurality of first inorganic portions, each first inorganic portion of the plurality of first inorganic portions is disposed between a respective one light-emitting unit of the plurality of light-emitting units and a respective one microlens portion of the plurality of microlens portions, and the second inorganic layer is disposed on a side of the reflective layer facing away from the substrate.

5. The display panel of claim 4, wherein each of a plurality of stacked units comprises a respective one of the plurality of light-emitting units, a respective one of the plurality of first inorganic portions, and a respective one of the plurality of microlens portion arranged in a stack; and
in a direction parallel to a plane in which the substrate is located, the plurality of stacked units are arranged with spacings, and part of the refractive layer extends into space between two of the plurality of stacked units.

6. The display panel of claim 1, further comprising at least one of:
the microlens portion has the refractive index ranging from 1.4 to 1.6; or,
the refractive layer has the refractive index ranging from 1.6 to 1.8.

7. The display panel of claim 1, wherein a light-emitting unit of the plurality of light-emitting units comprises a first light-emitting unit and a second light-emitting unit, and a wavelength of light emitted by the first light-emitting unit is greater than a wavelength of light emitted by the second light-emitting unit; and
a refractive index of a microlens portion disposed on a side of the first light-emitting unit facing away from the substrate is greater than a refractive index of a microlens portion disposed on a side of the second light-emitting unit facing away from the substrate.

8. The display panel of claim 1, wherein a light-emitting unit of the plurality of light-emitting units comprises a first light-emitting unit and a second light-emitting unit, and a wavelength of light emitted by the first light-emitting unit is greater than a wavelength of light emitted by the second light-emitting unit; and
in a direction perpendicular to a plane in which the substrate is located, thickness of a microlens portion disposed on a side of the first light-emitting unit facing away from the substrate is smaller than thickness of a microlens portion disposed on a side of the second light-emitting unit facing away from the substrate.

9. The display panel of claim 1, wherein the microlens portion and the refractive layer each comprise an acrylic material.

10. The display panel of claim 9, wherein the refractive layer comprises a zirconium oxide material.

11. The display panel of claim 1, further comprising an isolation structure disposed on the one side of the substrate, wherein the isolation structure comprises an isolation opening, a light-emitting unit of the plurality of light-emitting units is at least partially located within the isolation opening, and an orthographic projection of the microlens portion on the substrate overlaps an orthographic projection of the isolation structure on the substrate.

12. A method for preparing a display panel, comprising:
providing a substrate;
forming a light-emitting unit material layer on one side of the substrate;
forming a plurality of microlens portions on a side of the light-emitting unit material layer facing away from the substrate, wherein the plurality of microlens portions comprise an etch-resistant material;
etching the light-emitting unit material layer with the plurality of microlens portions as shields to form a plurality of light-emitting units; and
forming a refractive layer at least on a side of the plurality of microlens portions facing away from the substrate, wherein a refractive index of the refractive layer is greater than a refractive index of a microlens portion of the plurality of microlens portions.

13. The method for preparing the display panel of claim 12, wherein between forming the light-emitting unit material layer on the one side of the substrate and forming the plurality of microlens portions on the side of the light-emitting unit material layer facing away from the substrate, the method further comprises forming a first inorganic layer on the side of the light-emitting unit material layer facing away from the substrate; and
etching the light-emitting unit material layer with the plurality of microlens portions as the shields to form the plurality of light-emitting units comprises:
etching the first inorganic layer and the light-emitting unit material layer with the plurality of microlens portions as the shields to form a plurality of first inorganic portions and the plurality of light-emitting units.

14. The method for preparing the display panel of claim 12, wherein forming the plurality of microlens portions on the side of the light-emitting unit material layer facing away from the substrate comprises:
forming the plurality of microlens portions on the side of the light-emitting unit material layer facing away from the substrate by inkjet printing process.

15. The method for preparing the display panel of claim 12, wherein forming the refractive layer at least on the side of the plurality of microlens portions facing away from the substrate comprises:
forming the refractive layer at least on the side of the plurality of microlens portions facing away from the substrate by inkjet printing process.

16. A display device, comprising: a display panel,
wherein the display panel comprises
a substrate;
a plurality of light-emitting units, disposed on one side of the substrate;
a plurality of microlens portions, wherein each microlens portion of the plurality of microlens portions is disposed on a side of a respective one light-emitting unit of the plurality of light-emitting units facing away from the substrate, and each microlens portion comprises an etch-resistant material; and
a refractive layer, disposed at least on a side of the plurality of microlens portions facing away from the substrate, wherein a refractive index of the refractive layer is greater than a refractive index of a microlens portion of the plurality of microlens portions.

17. The display device of claim 16, wherein the microlens portion has a tapered structure in a direction from the substrate to a light-emitting unit of the plurality of light-emitting units.

18. The display device of claim 17, wherein a cross section of the microlens portion is at least one of a semicircle, a triangle, or a trapezoid in a direction perpendicular to a plane in which the substrate is located.

19. The display device of claim 16, further comprising a first inorganic layer and a second inorganic layer, wherein the first inorganic layer comprises a plurality of first inorganic portions, each first inorganic portion of the plurality of first inorganic portions is disposed between a respective one light-emitting unit of the plurality of light-emitting units and a respective one microlens portion of the plurality of microlens portions, and the second inorganic layer is disposed on a side of the reflective layer facing away from the substrate.

20. The display device of claim 19, wherein each of a plurality of stacked units comprises a respective one of the plurality of light-emitting units, a respective one of the plurality of first inorganic portions, and a respective one of the plurality of microlens portion arranged in a stack; and
in a direction parallel to a plane in which the substrate is located, the plurality of stacked units are arranged with spacings, and part of the refractive layer extends into space between two of the plurality of stacked units.
